(19) United States
(12) Patent Application Publication
(10) Pub. No.: US 2020/0379338 A1
(43) Pub. Date: Dec. 3, 2020

(54) MASK BLANK, PHASE SHIFT MASK, AND METHOD OF MANUFACTURING SEMICONDUCTOR DEVICE

(71) Applicants: HOYA CORPORATION, Tokyo (JP); HOYA ELECTRONICS SINGAPORE PTE. LTD., Singapore (SG)

(72) Inventors: Hiroaki SHISHIDO, Tokyo (JP); Masahiro HASHIMOTO, Tokyo (JP); Takashi UCHIDA, Tokyo (JP); Mariko UCHIDA, Singapore (SG)

(73) Assignees: HOYA CORPORATION, Tokyo (JP); HOYA ELECTRONICS SINGAPORE PTE. LTD., Singapore (SG)

(21) Appl. No.: 16/955,002

(22) PCT Filed: Oct. 31, 2018
(86) PCT No.: PCT/JP2018/040505

§ 371 Date: Jun. 17, 2020

(30) Foreign Application Priority Data
Dec. 26, 2017 (JP) 2017-248999

(51) Int. Cl. G03F 1/32; G03F 1/54

(52) U.S. Cl. CPC G03F 1/32; G03F 1/54

(57) ABSTRACT

In a mask blank, a phase shift film in contact with a transparent substrate includes a stack of two or more layers including a lowermost layer. The, layers other than the lowermost layer are made of a material consisting of silicon and one or more elements selected from a metalloid element and anon-metallic element. The lowermost layer is made of a material consisting of silicon and nitrogen and, optionally, one or more elements selected from a metalloid element and anon-metallic element. A ratio of a number of Si₃N₄ bonds present in the lowermost layer to a total number of Si₃N₄ bonds, SiₐN_{b} bonds (provided that b/[a+b]<4/7), and Si—Si bonds present is 0.05 or less. A ratio of a number of SiₐN_{b} bonds present in the lowermost layer to a total number of Si₃N₄ bonds, SiₐN_{b} bonds, and Si—Si bonds present is 0.1 or more.

### CROSS-REFERENCE TO RELATED APPLICATIONS

This application is a National Stage of International Application No. PCT/JP2018/040505, filed Oct. 31, 2018, which claims priority to Japanese Patent Application No. 2017-248999, filed Dec. 26, 2017, and the contents of which is incorporated by reference.

### TECHNICAL FIELD

This disclosure relates to a mask blank and a phase shift mask manufactured using the mask blank. This disclosure further relates to a method of manufacturing a semiconductor device using the phase shift mask.

### BACKGROUND ART

In a manufacturing process of a semiconductor device, a fine pattern is formed using a photolithography method. A number of transfer masks are usually used to form the fine pattern. In order to miniaturize a pattern of a semiconductor device, in addition to miniaturization of a mask pattern formed on a transfer mask, it is necessary to shorten a wavelength of an exposure light source used in photolithography. In recent years, application of an ArF excimer laser (wavelength 193 nm) is increasing as an exposure light source in the manufacture of a semiconductor device.

A type of a transfer mask is a half tone phase shift mask. A molybdenum silicide (MoSi)-based material is widely used for a phase shift film of a half tone phase shift mask. However, it has been discovered recently that a MoSi-based film has a low resistance to an exposure light of an ArF excimer laser (so-called ArF light fastness), as disclosed in Patent Document 1. In Patent Document 1, ArF light fastness is enhanced by subjecting a MoSi-based film after formation of a pattern under plasma treatment, UV irradiation treatment, or heat treatment to form a passivation film on a surface of the pattern of the MoSi-based film.

Patent Document 2 discloses a phase shift mask including an SiNx phase shift film, and Patent Document 3 describes that an SiNx phase shift film was confirmed as having high ArF light fastness. On the other hand, Patent Document 4 discloses a defect repairing technique where xenon difluoride (XeF₂) gas is supplied to a black defect portion of a light shielding film while irradiating the portion with an electron beam to etch and remove the black defect portion (defect repair by irradiating charged particles such as an electron beam as above is hereafter simply referred to as EB defect repair).

### PRIOR ART PUBLICATIONS

### Patent Documents

### [Patent Document 1]

Japanese Patent Application Publication 2010-217514

### [Patent Document 2]

Japanese Patent Application Publication H08-220731

### [Patent Document 3]

Japanese Patent Application Publication 2014-137388

### [Patent Document 4]

PCT Application Japanese Translation Publication 2004-537758

### SUMMARY OF THE DISCLOSURE

### Problems to be Solved by the Disclosure

Generally, a phase shift film requires to have a function to transmit an exposure light entering the phase shift film at a predetermined transmittance and also a function to generate a predetermined phase difference between the exposure light transmitted through the phase shift film and the exposure light transmitted through the air for a same distance as a thickness of the phase shift film. A refractive index n and an extinction coefficient k to an exposure light of a thin film made of MoSi-based materials such as MoSiN and MoSiON can be adjusted by adjusting the content amount of each of molybdenum (Mo), nitrogen (N), and oxygen (O), and the adjustable range is relatively large. Therefore, in the case of making a phase shift film of a single layer structure from a MoSi-based material, the adjustable range of a transmittance and a phase difference is relatively large.

On the other hand, while a refractive index n and an extinction coefficient k to an exposure light of a thin film made of silicon-based materials such as SiN, SiO, and SiON can be adjusted by adjusting the content amount of each of nitrogen (N) and oxygen (O), the adjustable range is relatively small. Therefore, in the case of making a phase shift film of a single layer structure from a silicon-based material, the adjustable range of a transmittance and a phase difference is relatively small. Thus, consideration was made to form a phase shift film of a silicon-based material with a stacked structure of two or more layers. Specifically, studied was a phase shift film including an SiN-based material layer with a relatively low nitrogen content and a silicon-based material layer with a relatively high nitrogen content.

An SiN-based material layer with a relatively low nitrogen content is often designed to have reduced film thickness due to high reduction rate of transmittance per unit film thickness. In an SiN-based material layer with a relatively low nitrogen content, oxidization is relatively likely to advance due to cleaning and the surface contacting the atmosphere. Further, an SiN-based material layer with a relatively low nitrogen content has relatively large reduction rate of transmittance by advancement of oxidization. Considering these points, a preferable configuration of a phase shift film includes providing an SiN-based material layer with a low nitrogen content as a lowermost layer at a position in contact with a transparent substrate, and a silicon-based material layer with a high nitrogen content on the lowermost layer as other layers. However, two major problems were discovered when a phase shift film simply configured as above was subjected to an EB defect repair on a black defect portion found on a transfer pattern of the phase shift film.

One major problem is that when an EB defect repair was performed to remove a black defect portion of a transfer pattern of a phase shift film, a surface of a transparent substrate in a region where the black defect existed is extremely roughened (surface roughness is significantly deteriorated). A region of a surface of a phase shift mask which is roughened after an EB defect repair is a region which becomes a light transmitting portion for transmitting an ArF exposure light. When a surface roughness of a substrate of a light transmitting portion is significantly deteriorated, it is likely to cause reduction in transmittance of an ArF exposure light, occurrence of diffused reflection, etc. Such a phase shift mask causes a significant reduction in transfer accuracy when placed on a mask stage of an exposure apparatus and used for exposure transfer.

Another major problem is that when an EB defect repair is performed to remove a black defect portion of a transfer pattern of the phase shift film, a transfer pattern existing around the black defect portion is etched from a side wall (this phenomenon is called spontaneous etching). When a spontaneous etching occurs, a transfer pattern becomes much thinner than the width before an EB defect repair. In the case of a transfer pattern having a thin width at the stage before an EB defect repair, there is a risk of falling off or loss of the pattern. Such a phase shift mask having a transfer pattern of a phase shift film where a spontaneous etching is likely to occur causes a significant reduction in transfer accuracy when the phase shift mask is placed on a mask stage of an exposure apparatus and used for exposure transfer.

Thus, this disclosure was made to solve the conventional problems, and an aspect of this disclosure is to provide a mask blank which, when an EB defect repair was performed, generation of a surface roughness of a transparent substrate can be suppressed, and generation of a spontaneous etching in a pattern of a phase shift film is also suppressed. A further aspect of this disclosure is to provide a phase shift mask manufactured using the mask blank. Yet another aspect of this disclosure is to provide a method of manufacturing a semiconductor device using such a phase shift mask.

### Means for Solving the Problem

For solving the above problems, this disclosure includes the following configurations.

### (Configuration 1)

A mask blank including a phase shift film on a transparent substrate, in which:

the phase shift film includes a stacked structure of two or more layers including a lowermost layer in contact with the transparent substrate,

one or more layers other than the lowermost layer of the phase shift film are made of a material consisting of silicon and one or more elements selected from a metalloid element and a non-metallic element,

the lowermost layer is made of a material consisting of silicon and nitrogen, or a material consisting of silicon, nitrogen, and one or more elements selected from a metalloid element and a non-metallic element,

a ratio calculated by dividing a number of Si₃N₄ bonds being present in the lowermost layer by a total number of Si₃N₄ bonds, SiₐN_{b} bonds (provided that b/[a+b]<4/7), and Si—Si bonds being present in the lowermost layer is 0.05 or less, and a ratio calculated by dividing a number of SiₐN_{b} bonds being present in the lowermost layer by a total number of Si₃N₄ bonds, SiₐN_{b} bonds, and Si—Si bonds being present in the lowermost layer is 0.1 or more.

### (Configuration 2)

The mask blank according to Configuration 1, in which the one or more layers other than the lowermost layer have a total content of nitrogen and oxygen of 50 atom % or more.

### (Configuration 3)

The mask blank according to Configuration 1 or 2, in which at least one of the layers other than the lowermost layer has a nitrogen content of 50 atom % or more.

### (Configuration 4)

The mask blank according to any one of Configurations 1 to 3, in which the lowermost layer is made of a material consisting of silicon, nitrogen, and a non-metallic element.

### (Configuration 5)

The mask blank according to any one of Configurations 1 to 4, in which at least one layer of the layers other than the lowermost layer has a ratio calculated by dividing a number of Si₃N₄ bonds being present in the one layer by a total number of Si₃N₄ bonds, SiₐN_{b} bonds, Si—Si bonds, Si—O bonds, and Si—ON bonds being present in the one layer of 0.87 or more.

### (Configuration 6)

The mask blank according to any one of Configurations 1 to 5, in which the lowermost layer has a thickness of 16 nm or less.

### (Configuration 7)

The mask blank according to any one of Configurations 1 to 6, in which the phase shift film has a function to transmit an exposure light of an ArF excimer laser at a transmittance of 2% or more, and a function to generate a phase difference of 150 degrees or more and 200 degrees or less between the exposure light transmitted through the phase shift film and the exposure light transmitted through air for a same distance as a thickness of the phase shift film.

### (Configuration 8)

The mask blank according to any one of Configurations 1 to 7 including a light shielding film on the phase shift film.

### (Configuration 9)

A phase shift mask including a phase shift film with a transfer pattern formed on a transparent substrate, in which:

the phase shift film includes a stacked structure of two or more layers including a lowermost layer in contact with the transparent substrate,

one or more layers other than the lowermost layer of the phase shift film are made of a material consisting of silicon and one or more elements selected from a metalloid element and a non-metallic element,

the lowermost layer is made of a material consisting of silicon and nitrogen, or a material consisting of silicon, nitrogen, and one or more elements selected from a metalloid element and a non-metallic element,

a ratio calculated by dividing a number of Si₃N₄ bonds being present in the lowermost layer by a total number of Si₃N₄ bonds, SiₐN_{b} bonds (provided that b/[a+b]<4/7), and Si—Si bonds being present in the lowermost layer is 0.05 or less, and

a ratio calculated by dividing a number of SiₐN_{b} bonds being present in the lowermost layer by a total number of Si₃N₄ bonds, SiₐN_{b} bonds, and Si—Si bonds being present in the lowermost layer is 0.1 or more.

### (Configuration 10)

The phase shift mask according to Configuration 9, in which the one or more layers other than the lowermost layer have a total content of nitrogen and oxygen of 50 atom % or more.

### (Configuration 11)

The phase shift mask according to Configuration 9 or 10, in which at least one layer of the layers other than the lowermost layer has a nitrogen content of 50 atom % or more.

### (Configuration 12)

The phase shift mask according to any one of Configurations 9 to 11, in which the lowermost layer is made of a material consisting of silicon, nitrogen, and a non-metallic element.

### (Configuration 13)

The phase shift mask according to any one of Configurations 9 to 12, in which at least one layer of the layers other than the lowermost layer has a ratio calculated by dividing a number of Si₃N₄ bonds being present in the one layer by a total number of Si₃N₄ bonds, SiₐN_{b} bonds, Si—Si bonds, Si—O bonds, and Si—ON bonds being present in the one layer of 0.87 or more.

### (Configuration 14)

The phase shift mask according to any one of Configurations 9 to 13, in which the lowermost layer has a thickness of 16 nm or less.

### (Configuration 15)

The phase shift mask according to any one of Configurations 9 to 14, in which the phase shift film has a function to transmit an exposure light of an ArF excimer laser at a transmittance of 2% or more, and a function to generate a phase difference of 150 degrees or more and 200 degrees or less between the exposure light transmitted through the phase shift film and the exposure light transmitted through air for a same distance as a thickness of the phase shift film.

### (Configuration 16)

The phase shift mask according to any one of Configurations 9 to 15 including a light shielding film having a light shielding pattern formed on the phase shift film.

### (Configuration 17)

A method of manufacturing a semiconductor device including the step of using the phase shift mask according to any one of Configurations 9 to 16 and exposure-transferring a transfer pattern in a resist film on a semiconductor substrate.

### Effect of the Disclosure

The mask blank of this disclosure can suppress generation of surface roughness of a transparent substrate, and can also suppress generation of a spontaneous etching in a transfer pattern when an EB defect repair was performed on a black defect portion of the transfer pattern made of an SiN-based material.

The phase shift mask of this disclosure can suppress generation of surface roughness of a transparent substrate near a black defect portion, and can also suppress generation of a spontaneous etching in a transfer pattern of the phase shift film when an EB defect repair was performed on the black defect portion of a transfer pattern of the phase shift film during manufacture of the phase shift mask.

Therefore, the phase shift mask of this disclosure can have high transfer precision.

### BRIEF DESCRIPTION OF THE DRAWINGS

FIG. 1 is a cross-sectional view showing a configuration of a mask blank of an embodiment of this disclosure.

FIG. 2 is a cross-sectional view showing a manufacturing process of the phase shift mask according to an embodiment of this disclosure.

FIG. 3 shows a result of an X-ray photoelectron spectroscopy on a lower layer (lowermost layer) of the phase shift film of the mask blank according to Example 1 of this disclosure.

FIG. 4 shows a result of an X-ray photoelectron spectroscopy on a lower layer (lowermost layer) of the phase shift film of the mask blank according to Example 3 of this disclosure.

FIG. 5 shows a result of an X-ray photoelectron spectroscopy on a lower layer (lowermost layer) of the phase shift film of the mask blank according to Comparative Example 1 of this disclosure.

### EMBODIMENTS FOR CARRYING OUT THE DISCLOSURE

The present inventors diligently studied a configuration of a phase shift film where generation of surface roughness of a transparent substrate is suppressed, and also generation of a spontaneous etching in a transfer pattern of the phase shift film is suppressed when an EB defect repair was performed on a black defect portion of the transfer pattern of the phase shift film made of a stacked structure of two or more layers and having a lowermost layer made of an SiN-based material.

XeF₂ gas used in an EB defect repair is known as non-excited etching gas when carrying out an isotropic etching on a silicon-based material. The etching is carried out by the processes of surface adsorption of non-excited XeF₂ gas on a silicon-based material, separation into Xe and F, generation of higher-order fluoride of silicon, and volatilization. In an EB defect repair on a thin film pattern of a silicon-based material, non-excited fluorine-based gas such as XeF₂ gas is supplied to a black defect portion of the thin film pattern, the fluorine-based gas is adsorbed to the surface of the black defect portion, and an electron beam is irradiated on the black defect portion. As a result, silicon in the black defect portion is excited to accelerate binding with fluorine, and is volatilized as a higher-order fluoride of silicon much faster than without irradiation of the electron beam. Since it is difficult to prevent fluorine-based gas from being adsorbed to the thin film pattern around the black defect portion, the thin film pattern around the black defect portion is also etched during an EB defect repair. When etching silicon bound to nitrogen, it is necessary to break the bond between silicon and nitrogen in order for fluorine in XeF₂ gas to bind to silicon to form a higher-order fluoride of silicon. Since silicon is excited in the black defect portion irradiated with the electron beam, the bond with nitrogen is broken, and is bound to fluorine to be easily volatilized. On the other hand, silicon unbound to other elements can be regarded as in the state of being easily bound to fluorine. Therefore, silicon unbound to other elements tends to bind to fluorine and is easily volatilized even in an unexcited state without being irradiated with electron beams, or even in a thin film pattern around a black defect portion which is slightly affected by irradiation of electron beams. This is assumed as the mechanism of generation of a spontaneous etching.

In making a phase shift film of a single layer structure from an SiN-based material, it is necessary to have a relatively high nitrogen content. Therefore, a problem of a spontaneous etching upon an EB defect repair is unlikely to occur in such a phase shift film. On the other hand, in the case of a phase shift film of a stacked structure of two or more layers mentioned above, when an SiN-based material having a significantly low nitrogen content is used as the lowermost layer, it can be considered as having a low ratio of silicon in the film bound to nitrogen, and having high ratio of silicon unbound to other elements. Therefore, it can be considered that a problem regarding a spontaneous etching upon an EB defect repair is likely to occur in such a film.

Next, the present inventors studied increasing a nitrogen content in an SiN-based material forming the lowermost layer of a phase shift film. When a nitrogen content is significantly increased, an extinction coefficient k will become significantly low, which makes it necessary to significantly increase the thickness of the phase shift film including the lowermost layer, and repair rate upon an EB defect repair decreases. Considering the above, an EB defect repair was attempted with a lowermost layer of a phase shift film made of an SiN-based material having a certain increase in a nitrogen content formed on a transparent substrate. As a result, the phase shift film had sufficiently high repair rate in the black defect portion, and generation of a spontaneous etching was suppressed. However, a surface of the transparent substrate after the repair was conspicuously roughened. Repair rate of the black defect portion of the phase shift film being sufficiently large means that etching selectivity between the transparent substrate is sufficiently high, and there should have been no conspicuous roughening on the surface of the transparent substrate.

As a result of further diligent study, the present inventors found out that as a presence ratio of Si₃N₄ bonds in an SiN-based material forming a lowermost layer of a phase shift film becomes greater, the surface roughness of a transparent substrate upon an EB defect repair becomes conspicuous. The SiN-based material is considered as mainly containing Si—Si bonds that are unbound to elements other than silicon, Si₃N₄ bonds that are in stoichiometrically stable binding condition, and SiₐN_{b} bonds (provided that b/[a+b]<4/7; same hereinafter) that are in relatively unstable binding condition. Since binding energy of silicon and nitrogen is particularly strong in Si₃N₄ bond, it is difficult to break the bond between silicon and nitrogen to produce high-order fluoride bound to fluorine when an electron beam was irradiated to excite silicon. Further, when an SiN-based material forming a lowermost layer of a phase shift film has a low nitrogen content, a presence ratio of Si₃N₄ bonds in the material tends to be low.

Considering the above, the inventors of this disclosure set up the following hypothesis. Namely, in the case where a presence ratio of Si₃N₄ bonds in a lowermost layer of a phase shift film is low, distribution of Si₃N₄ bonds in planar view of a black defect portion is considered as sparse (uneven). When an electron beam is irradiated from above and an EB defect repair is performed on such a black defect portion, silicon in Si—Si bonds and SiₐN_{b} bonds binds to fluorine at an early stage and volatilizes. However, Si₃N₄ bonds require a great amount of energy to break the bond between silicon and nitrogen so that it takes time until silicon binds to fluorine and volatilizes. Accordingly, a significant difference generates in planar view in a removal amount of the black defect portion in a film thickness direction. Continuing the EB defect repair with such differences in the removal amount in planar view occurring in various locations in the film thickness direction will result in, in the black defect portion to which an electron beam is irradiated, formation of a region where an EB defect repair reaches a transparent substrate at an early stage and a surface of the transparent substrate is exposed, and a region where the EB defect repair does not reach up to the transparent substrate and the black defect portion still remains on the surface of the transparent substrate. Since it is technically difficult to irradiate an electron beam only on the region where the black defect portion remains, the region where the surface of the transparent substrate is exposed is also continuously irradiated with the electron beam during continuation of the EB defect repair for removing the region where the black defect portion remains. Since the transparent substrate is slightly etched to an EB defect repair, the surface of the transparent substrate is roughened until the EB defect repair is completed.

A diligent study was made based on the hypothesis. As a result, the inventors found out that when an EB defect repair was performed on a black defect portion of a phase shift film with a ratio of an amount of Si₃N₄ bonds being present in an SiN-based material forming a lowermost layer of the phase shift film, divided by a total number of Si₃N₄ bonds, SiₐN_{b} bonds, and Si—Si bonds being present in the SiN-based material is a certain value or less, the surface roughness of the transparent substrate of the region where the black defect portion existed can be reduced to a degree where there is substantially no influence upon exposure transfer when used as a phase shift mask. Concretely, a surface roughness of a transparent substrate associated with an EB defect repair can be significantly suppressed when a ratio calculated by dividing a number of Si₃N₄ bonds being present in a lowermost layer of a phase shift film by a total number of Si₃N₄ bonds, SiₐN_{b} bonds (provided that b/[a+b]<4/7), and Si—Si bonds being present in the lowermost layer is 0.05 or less.

Furthermore, the inventors found out that, when the ratio calculated by dividing the number of SiₐN_{b} bonds being present in the lowermost layer of the phase shift film by a total number of Si₃N₄ bonds, SiₐN_{b} bonds, and Si—Si bonds being present is 0.1 or more, there will be a certain ratio or more of silicon bound to nitrogen in the lowermost layer of the phase shift film, and when an EB defect repair was performed on the black defect portion, occurrence of a spontaneous etching on a transfer pattern side wall around the black defect portion can be significantly suppressed.

This disclosure has been completed as a result of the diligent studies described above.

Next, the embodiments of this disclosure are described.

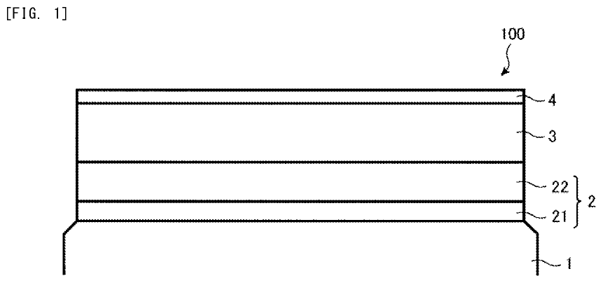

FIG. 1 is a cross-sectional view showing a configuration of a mask blank 100 of an embodiment of this disclosure. The mask blank 100 of this disclosure shown in FIG. 1 has a structure where a phase shift film 2, a light shielding film 3, and a hard mask film 4 are stacked in this order on a transparent substrate 1.

The transparent substrate 1 can be made of quartz glass, aluminosilicate glass, soda-lime glass, low thermal expansion glass (SiO₂—TiO₂ glass, etc.), etc., in addition to synthetic quartz glass. Among the above, synthetic quartz glass is particularly preferable as a material for forming the transparent substrate 1 of the mask blank for having a high transmittance to an ArF excimer laser light. A refractive index n of the material forming the transparent substrate 1 to ArF exposure light wavelength (about 193 nm) is preferably 1.5 or more and 1.6 or less, more preferably 1.52 or more and 1.59 or less, and even more preferably 1.54 or more and 1.58 or less.

A transmittance of the phase shift film 2 to an ArF exposure light is preferably 2% or more. This is to generate a sufficient phase shift effect between the exposure light transmitted through the interior of the phase shift film 2 and the exposure light transmitted through the air. A transmittance of the phase shift film 2 to an exposure light is preferably 3% or more, and more preferably 4% or more. Further, a transmittance of the phase shift film 2 to an exposure light is preferably 40% or less, and more preferably 35% or less.

To obtain a proper phase shift effect, it is desirable for the phase shift film 2 to be adjusted such that a phase difference that generates between the transmitting ArF exposure light and the light that transmitted through the air for the same distance as a thickness of the phase shift film 2 is within the range of 150 degrees or more and 200 degrees or less. The phase difference in the phase shift film 2 is preferably 155 degrees or more, and more preferably 160 degrees or more. On the other hand, the phase difference of the phase shift film 2 is preferably 195 degrees or less, and more preferably 190 degrees or less.

The phase shift film 2 has a structure where a lower layer 21 and an upper layer 22 are stacked from the transparent substrate 1 side. In this embodiment, the lower layer 21 is the lowermost layer in contact with the transparent substrate 1. To at least satisfy each condition of the transmittance and the phase difference in the entire phase shift film 2, a refractive index n of the lower layer 21 to a wavelength of an ArF exposure light (hereafter simply referred to as refractive index n) is preferably 1.55 or less. Further, a refractive index n of the lower layer 21 is preferably 1.25 or more. An extinction coefficient k of the lower layer 21 is preferably 2.00 or more. Further, an extinction coefficient k of the lower layer 21 to a wavelength of an ArF exposure light (hereafter simply referred to as extinction coefficient k) is preferably 2.40 or less. A refractive index n and an extinction coefficient k of the lower layer 21 are values derived by regarding the entire lower layer 21 as a single, optically uniform layer.

For the phase shift film 2 to satisfy the above conditions, a refractive index n of the upper layer 22 is preferably 2.30 or more, and more preferably 2.40 or more. Further, a refractive index n of the upper layer 22 is preferably 2.80 or less, and more preferably 2.70 or less. An extinction coefficient k of the upper layer 22 is preferably 1.00 or less, and more preferably 0.90 or less. Further, an extinction coefficient k of the upper layer 22 is preferably 0.20 or more, and more preferably 0.30 or more. A refractive index n and an extinction coefficient k of the upper layer 22 are values derived by regarding the entire upper layer 22 including a surface layer portion to be described below as a single, optically uniform layer.

A refractive index n and an extinction coefficient k of a thin film including the phase shift film 2 are not determined only by the composition of the thin film. Film density and the crystal condition of the thin film are also the factors that affect a refractive index n and an extinction coefficient k. Therefore, the conditions in forming a thin film by reactive sputtering are adjusted so that the thin film reaches a desired refractive index n and extinction coefficient k. For allowing the lower layer 21 and the upper layer 22 to have a refractive index n and an extinction coefficient k of the above range, not only the ratio of mixed gas of noble gas and reactive gas (oxygen gas, nitrogen gas, etc.) is adjusted in forming a film by reactive sputtering, but various other adjustments are made upon forming a film by reactive sputtering, such as pressure in a film forming chamber, power applied to the sputtering target, and positional relationship such as distance between the target and the transparent substrate 1. These film forming conditions are specific to a film forming apparatus, and are adjusted arbitrarily for the lower layer 21 and the upper layer 22 to be formed to achieve desired refractive index n and extinction coefficient k.

It is desirable that the thickness of the lower layer 21 is as small as possible within the scope capable of satisfying the conditions of predetermined transmittance and phase difference required for the phase shift film 2. The thickness of the lower layer 21 is preferably 16 nm or less, more preferably 14 nm or less, and even more preferably 12 nm or less. Particularly considering the back-surface reflectance of the phase shift film 2, the thickness of the lower layer 21 is preferably 2 nm or more, more preferably 3 nm or more, and even more preferably 5 nm or more. Incidentally, in the case of making the phase shift film 2 with three or more layers, the thickness of the lowermost layer corresponds to the thickness of the lower layer 21.

The thickness of the upper layer 22 is preferably 80 nm or less, more preferably 70 nm or less, and even more preferably 65 nm or less. Further, the thickness of the upper layer 22 is preferably 40 nm or more, and more preferably 45 nm or more. Incidentally, in the case of making the phase shift film 2 with three or more layers, the thickness of the layers other than the lowermost layer corresponds to the thickness of the upper layer 22.

The lower layer 21 is made of a material consisting of silicon and nitrogen, or a material consisting of silicon, nitrogen, and one or more elements selected from a metalloid element and a non-metallic element. Among the metalloid elements, it is preferable to include one or more elements selected from boron, germanium, antimony, and tellurium, since enhancement in conductivity of silicon to be used as a sputtering target can be expected.

While silicon tends to cause a spontaneous etching upon EB defect repair for generating fluoride with low boiling point when bound to fluorine, a metalloid element generates fluoride with a boiling point higher than the case of silicon when bound to fluorine. Therefore, containing a metalloid element in the lower layer 21 does not cause easier occurrence of a spontaneous etching. Generally in an EB defect repair, an adjustment is made so that the lower layer 21 to be repaired and a transparent substrate including silicon oxide as a main component have sufficiently large repair rate difference. A metalloid element tends have faster repair rate than silicon. Moreover, as the repair rate increases, a surface roughness on the transparent substrate tends to be unlikely to occur upon an EB defect repair.

In view of the above, including a metalloid element in the lower layer 21 is considered as preferable on the viewpoint of an EB defect repair. On the other hand, as a content amount of a metalloid element in the lower layer 21 increases, a change that cannot be ignored occurs in optical properties of the lower layer 21. Considering these points comprehensively, a content amount of a metalloid element in the lower layer 21 is preferably 10 atom % or less, more preferably 5 atom % or less, and even more preferably 3 atom % or less.

While an influence on the repair rate upon an EB defect repair is significant by including oxygen in the lower layer 21, it is difficult to avoid oxygen entering the lower layer 21 upon its formation. An influence on the repair rate upon an EB defect repair in the lower layer 21 can be reduced when the lower layer 21 has an oxygen content of 3 atom % or less. An oxygen content of the lower layer 21 is preferably 2 atom % or less, more preferably 1 atom % or less, and even more preferably detection lower limit or less through analysis of X-ray photoelectron spectroscopy.

In the case of including a non-metallic element other than nitrogen in the lower layer 21, it is preferable to include one or more elements selected from carbon, fluorine, and hydrogen among the non-metallic elements. There is relatively small influence on the repair rate of an EB defect repair by including the non-metallic elements listed above in the lower layer 21. A content of the non-metallic elements listed above in the lower layer 21 is preferably 5 atom % or less, more preferably 3 atom % or less, and even more preferably detection lower limit or less through analysis of X-ray photoelectron spectroscopy. On the other hand, non-metallic elements that can be included in the lower layer 21 other than nitrogen include noble gas such as helium (He), argon (Ar), krypton (Kr), and xenon (Xe). Containing noble gas in the lower layer 21 does not cause a substantial change in the tendency of the lower layer 21 upon an EB defect repair. The lower layer 21 is preferably made of a material consisting of silicon, nitrogen, and a non-metallic element.

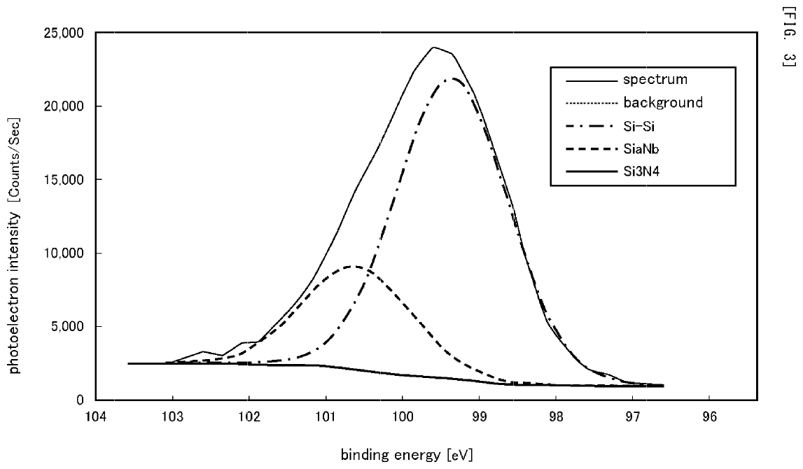

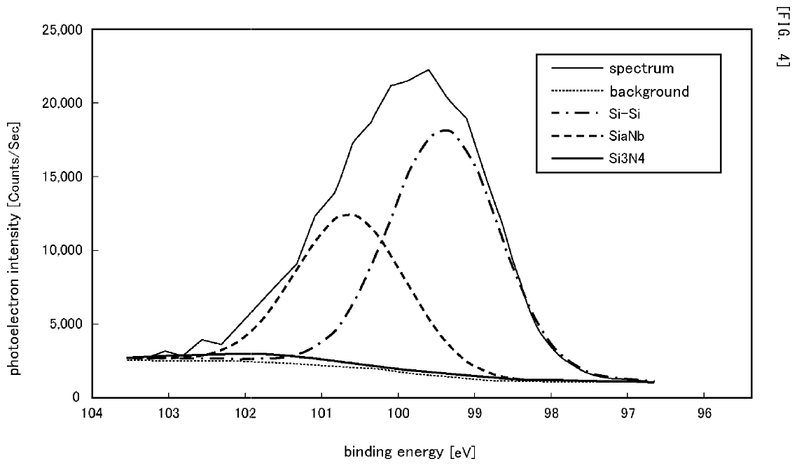

In the lower layer 21, a ratio calculated by dividing the number of Si₃N₄ bonds being present by a total number of Si₃N₄ bonds and SiₐN_{b} bonds (where a relationship b/[a+b]<4/7 is satisfied) is 0.05 or less; and a ratio calculated by dividing the number of SiₐN_{b} bonds being present by a total number of Si₃N₄ bonds, SiₐN_{b} bonds, and Si—Si bonds being present is 0.1 or more. These points are described below along with FIGS. 3 and 4. The lower layer 21 has a total content of silicon and nitrogen of preferably 97 atom %, and more preferably, is made of a material having 98 atom % or more. On the other hand, the lower layer 21 has a difference of content amount of each element constructing the lower layer 21 in the film thickness direction of preferably less than 10% or less, and more preferably 5% or less. This is for reducing variation in repair rate in removing the lower layer 21 by an EB defect repair.

The upper layer 22 is made of a material consisting of silicon and one or more elements selected from a metalloid element and a non-metallic element. Among the metalloid elements, it is preferable to include one or more elements selected from boron, germanium, antimony, and tellurium, since enhancement in conductivity of silicon to be used as a sputtering target can be expected. Among the non-metallic elements, it is preferable to include one or more elements selected from nitrogen, carbon, fluorine, and hydrogen. These non-metallic elements include noble gas such as helium (He), argon (Ar), krypton (Kr), and xenon (Xe).

A total content of nitrogen and oxygen of the material making the upper layer 22 is preferably 50 atom % or more, and more preferably, a nitrogen content of 50 atom % or more. Further, an oxygen content of the upper layer 22 is preferably 10 atom % or less, more preferably 5 atom % or less, and even more preferably 3 atom % or less. It is preferable that in the material making the upper layer 22, a ratio calculated by dividing a number of Si₃N₄ bonds being present by a total number of Si₃N₄ bonds, SiₐN_{b} bonds, Si—Si bonds, Si—O bonds, and Si—ON bonds being present is 0.87 or more. Making the upper layer 22 using such materials results in relatively uniform distribution of Si₃N₄ bonds in plan view of the upper layer 22, and is less likely to be sparse. Therefore, it is preferable in that the upper layer 22 of the repaired portion upon an EB defect repair can be uniformly removed, and an influence on the lower layer 21 can be suppressed.

Further, an uppermost layer (not shown) can be provided on the upper layer 22. The uppermost layer in this case is preferably made of a material consisting of silicon and oxygen, or a material consisting of silicon, oxygen, and one or more elements selected from a metalloid element and a non-metallic element. An oxygen content of the uppermost layer is preferably 40 atom % or more, more preferably 50 atom % or more, and even more preferably 60 atom % or more. With 40 atom % or more oxygen content of the uppermost layer, a majority of the interior of the uppermost layer is occupied by SiO₂ bonds, and distribution of SiO₂ bonds in plan view of the uppermost layer is uniform and less likely to become sparse. Therefore, the uppermost layer of the repaired portion upon an EB defect repair can be uniformly removed, and an influence on the lower layer 21 can be suppressed.

On the other hand, in the case of not providing the uppermost layer mentioned above, the material making the uppermost layer 22 can be a material consisting of silicon and oxygen, or a material consisting of silicon, oxygen, and one or more elements selected from a metalloid element and a non-metallic element. In this case, an oxygen content of the upper layer 22 is preferably 40 atom % or more, more preferably 50 atom % or more, and even more preferably 60 atom % or more. With 40 atom % or more oxygen content of the upper layer 22, a majority of the interior of the upper layer 22 is occupied by SiO₂ bonds, and distribution of SiO₂ bonds in plan view of the upper layer 22 is uniform and less likely to become sparse. Therefore, the upper layer 22 of the repaired portion upon an EB defect repair can be uniformly removed, and an influence on the lower layer 21 can be suppressed.

While the lower layer 21 and the upper layer 22 of the phase shift film 2 are made through sputtering, any sputtering including DC sputtering, RF sputtering, ion beam sputtering, etc. is applicable. Application of DC sputtering is preferable, considering film forming rate. In the case where the target has low conductivity, while application of RF sputtering and ion beam sputtering is preferable, application of RF sputtering is more preferable considering film forming rate.

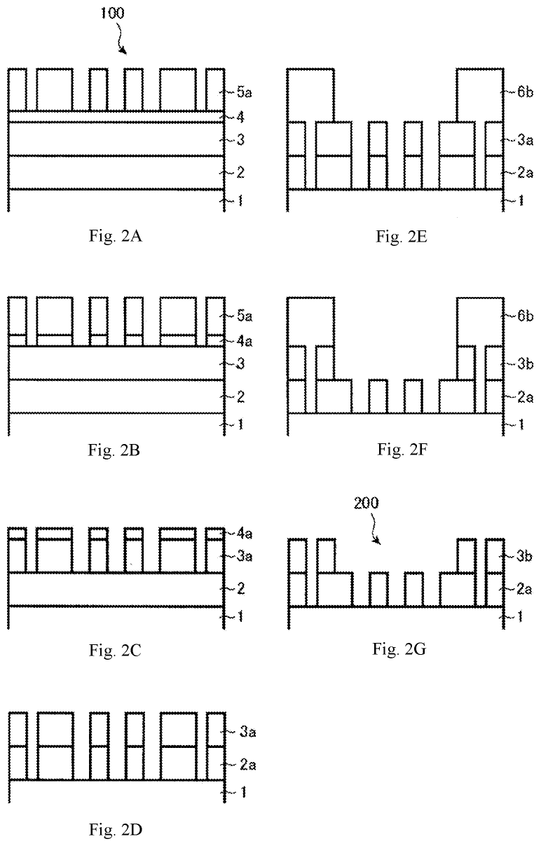

It is preferable that the phase shift film 2 in this embodiment in the state where only the phase shift film 2 is present on the transparent substrate 1 has 35% or more reflectance at the transparent substrate 1 side (back surface side) to an ArF exposure light (back surface reflectance). The state where only the phase shift film 2 is present on the transparent substrate 1 indicates a state where a light shielding pattern 3b is not stacked on a phase shift pattern 2a (region of phase shift pattern 2a where light shielding pattern 3b is not stacked) when a phase shift mask 200 (see FIG. 2(g)) is manufactured from this mask blank 100. It is difficult to increase a back surface reflectance in a phase shift film of a single layer structure, and with a phase shift film of a stacked structure of two or more layers including a lowermost layer as in this embodiment, it is possible to increase a back surface reflectance than conventional cases. With the phase shift mask 200 having such a back surface reflectance, absorption of an ArF exposure light within the phase shift pattern 2a can be reduced. Thus, the amount of heat generated by absorption of an ArF exposure light being transformed into heat within the phase shift pattern 2a can be reduced. Accordingly, reduction can be made on the thermal expansion of the transparent substrate 1 caused by heating of the phase shift pattern 2a and movement of the phase shift pattern 2a caused thereby.

Although the phase shift film 2 of this embodiment is made of a stacked structure of two layers including the lower layer 21 and the upper layer 22, the phase shift film 2 can be made of a stacked structure of three or more layers. When the phase shift film 2 is made of a stacked structure in the order of a lowermost layer contacting the surface of the transparent substrate, an intermediate layer, and an upper layer from the transparent substrate 1 side, it is preferable to be configured such that refractive indexes n₁, n₂, and n₃ of the lowermost layer, the intermediate layer, and the upper layer, respectively, at the wavelength of an exposure light satisfy the relations of n₁<n₂ and n₂>n₃; and extinction coefficients k₁, k₂, and k₃ of the lowermost layer, the intermediate layer, and the upper layer, respectively, at the wavelength of an exposure light satisfy the relation of k₁>k₂>k₃. With such a configuration of the phase shift film 2, thermal expansion of the pattern of the phase shift film 2 (phase shift pattern 2a) can be prevented, and movement of the phase shift pattern 2a caused thereby can be prevented.

The mask blank 100 has a light shielding film 3 on the phase shift film 2. Generally, in a binary transfer mask, an outer peripheral region of a region where a transfer pattern is formed (transfer pattern forming region) is desired to ensure an optical density (OD) of a predetermined value or more to prevent the resist film from being subjected to an influence of an exposure light that transmitted through the outer peripheral region when an exposure transfer was made on the resist film on a semiconductor wafer using an exposure apparatus. This point is similar in the case of a phase shift mask. The outer peripheral region of a phase shift mask preferably has an OD of 2.8 or more, and more preferably 3.0 or more. The phase shift film 2 has a function to transmit an exposure light at a predetermined transmittance, and it is difficult to ensure an optical density of a predetermined value with the phase shift film 2 alone. Therefore, it is necessary to stack the light shielding film 3 on the phase shift film 2 to ensure lacking optical density at the stage of manufacturing the mask blank 100. With such a configuration of the mask blank 100, the phase shift mask 200 ensuring a predetermined value of optical density on the outer peripheral region can be manufactured by removing the light shielding film 3 of the region using the phase shift effect (basically transfer pattern forming region) during manufacture of the phase shift mask 200 (see FIG. 2).

A single layer structure and a stacked structure of two or more layers are applicable to the light shielding film 3. Further, each layer in the light shielding film 3 of a single layer structure and the light shielding film 3 with a stacked structure of two or more layers may be configured by approximately the same composition in the thickness direction of the layer or the film, or with a composition gradient in the thickness direction of the layer.

The mask blank 100 in the embodiment shown in FIG. 1 is configured such that the light shielding film 3 is stacked on the phase shift film 2 without an intervening film. For the light shielding film 3 in the case of this configuration, it is necessary to apply a material having sufficient etching selectivity to etching gas used in forming a pattern in the phase shift film 2. The light shielding film 3 in this case is preferably made of a material containing chromium. Materials containing chromium for making the light shielding film 3 can include, in addition to chromium metal, a material containing chromium and one or more elements selected from oxygen, nitrogen, carbon, boron, and fluorine.

While a chromium-based material is generally etched by mixed gas of chlorine-based gas and oxygen gas, etching rate of the chromium metal to the etching gas is not as high. Considering enhancing etching rate of the mixed gas of chlorine-based gas and oxygen gas to etching gas, the material forming the light shielding film 3 preferably includes chromium and one or more elements selected from oxygen, nitrogen, carbon, boron, and fluorine. Further, one or more elements among molybdenum, indium, and tin may be included in the material containing chromium for forming the light shielding film 3. Including one or more elements among molybdenum, indium, and tin can increase etching rate to the mixed gas of chlorine-based gas and oxygen gas.

If an etching selectivity to dry etching between the material forming the upper layer 22 (esp., surface layer portion) can be obtained, the light shielding film 3 can be formed from a material containing a transition metal and silicon. A material containing a transition metal and silicon has high light shielding performance, which enables reduction of thickness of the light shielding film 3. The transition metal to be included in the light shielding film 3 includes one metal among molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), zinc (Zn), niobium (Nb), palladium (Pd), etc., or an alloy of these metals. Metal elements other than the transition metal elements to be included in the light shielding film 3 include aluminum (Al), indium (In), tin (Sn), gallium (Ga), etc.

On the other hand, the light shielding film 3 can have a structure where a layer consisting of a material containing chromium and a layer consisting of a material containing a transition metal and silicon are stacked, in this order, from the phase shift film 2 side. Concrete matters on the material containing chromium and the material containing a transition metal and silicon in this case are similar to the case of the light shielding film 3 described above.

In the mask blank 100, a preferable structure is that the light shielding film 3 has further stacked thereon a hard mask film 4 made of a material having etching selectivity to etching gas used in etching the light shielding film 3. Since the hard mask film 4 is not basically limited with regard to optical density, the thickness of the hard mask film 4 can be reduced significantly compared to the thickness of the light shielding film 3. Since the film thickness of a resist film of an organic material is sufficient if the film thickness functions as an etching mask until dry etching for forming a pattern in the hard mask film 4 is completed, the thickness can be reduced significantly compared to conventional resist films. Reduction of film thickness of a resist film is effective for enhancing resist resolution and preventing collapse of the pattern, which is extremely important in facing requirements for miniaturization.

In the case where the light shielding film 3 is made of a material containing chromium, the hard mask film 4 is preferably made of a material containing silicon. Since the hard mask film 4 in this case tends to have low adhesiveness with the resist film of an organic material, it is preferable to treat the surface of the hard mask film 4 with HMDS (Hexamethyldisilazane) to enhance surface adhesiveness. The hard mask film 4 in this case is more preferably made of SiO₂, SiN, SiON, etc.

Further, in the case where the light shielding film 3 is made of a material containing chromium, materials containing tantalum are also applicable as the materials of the hard mask film 4, in addition to the materials given above. The material containing tantalum in this case includes, in addition to tantalum metal, a material containing tantalum and one or more elements selected from nitrogen, oxygen, boron, and carbon, for example, Ta, TaN, TaO, TaON, TaBN, TaBO, TaBON, TaCN, TaCO, TaCON, TaBCN, and TaBOCN. Further, in the case where the light shielding film 3 is made of a material containing silicon, the hard mask film 4 is preferably made of the material containing chromium given above.

In the mask blank 100, a resist film of an organic material is preferably formed in contact with the surface of the hard mask film 4 at a film thickness of 100 nm or less. In the case of a fine pattern to meet DRAM hp32 nm generation, a SRAF (Sub-Resolution Assist Feature) with 40 nm line width may be provided on a transfer pattern (phase shift pattern) to be formed in the hard mask film 4. However, even in this case, cross-sectional aspect ratio of the resist pattern can be reduced down to 1:2.5 so that collapse and peeling off of the resist pattern can be prevented in rinsing and developing, etc. of the resist film. Incidentally, the resist film preferably has a film thickness of 80 nm or less.

FIG. 2 shows a phase shift mask 200 according to an embodiment of this disclosure manufactured from the mask blank 100 of the above embodiment, and its manufacturing process. As shown in FIG. 2(g), the phase shift mask 200 is featured in that a phase shift pattern 2a as a transfer pattern is formed in a phase shift film 2 of the mask blank 100, and a light shielding pattern 3b is formed in a light shielding film 3. In the case of a configuration where a hard mask film 4 is provided on the mask blank 100, the hard mask film 4 is removed during manufacture of the phase shift mask 200.

The method for manufacturing the phase shift mask of the embodiment of this disclosure uses the mask blank 100 mentioned above, which is featured in including the steps of forming a transfer pattern in the light shielding film 3 by dry etching; forming a transfer pattern in the phase shift film 2 by dry etching with the light shielding film 3 having the transfer pattern as a mask; and forming a light shielding pattern 3b in the light shielding film 3 by dry etching with a resist film (resist pattern 6b) having a light shielding pattern as a mask. The method of manufacturing the phase shift mask 200 of this disclosure is explained below according to the manufacturing steps shown in FIG. 2. Explained herein is the method of manufacturing the phase shift mask 200 using a mask blank 100 having a hard mask film 4 stacked on a light shielding film 3. Further, in this case, a material containing chromium is used in the light shielding film 3, and a material containing silicon is used in the hard mask film 4.

First, a resist film was formed in contact with the hard mask film 4 of the mask blank 100 by spin coating. Next, a first pattern, which is a transfer pattern (phase shift pattern) to be formed in the phase shift film 2, was exposed and written with an electron beam on the resist film, and a predetermined treatment such as developing was conducted, to thereby form a first resist pattern 5a having a phase shift pattern (see FIG. 2(a)). At this stage, a program defect was added to the resist pattern 5a that was written by electron beam in addition to the transfer pattern that is to be originally formed, so that a black defect is formed in the phase shift film 2. Subsequently, dry etching was conducted using fluorine-based gas with the first resist pattern 5a as a mask, and a first pattern (hard mask pattern 4a) was formed in the hard mask film 4 (see FIG. 2(b)).

Next, after removing the resist pattern 5a, dry etching was conducted using mixed gas of chlorine-based gas and oxygen gas with the hard mask pattern 4a as a mask, and a first pattern (light shielding pattern 3a) was formed in the light shielding film 3 (see FIG. 2(c)). Subsequently, dry etching was conducted using fluorine-based gas with the light shielding pattern 3a as a mask, a first pattern (phase shift pattern 2a) was formed in the phase shift film 2, and the hard mask pattern 4a was removed (see FIG. 2(d)).

Next, a resist film was formed on the mask blank 100 by spin coating. Next, a second pattern, which is a pattern (light shielding pattern) to be formed in the light shielding film 3, was exposed and written with an electron beam in the resist film, and a predetermined treatment such as developing was conducted, to thereby form a second resist pattern 6b having a light shielding pattern (see FIG. 2(e)). Subsequently, dry etching was conducted using mixed gas of chlorine-based gas and oxygen gas with the second resist pattern 6b as a mask, and a second pattern (light shielding pattern 3b) was formed in the light shielding film 3 (see FIG. 2(f)). Further, the second resist pattern 6b was removed, predetermined treatments such as cleaning were carried out, and the phase shift mask 200 was obtained (see FIG. 2(g)).

There is no particular limitation to chlorine-based gas to be used for the dry etching described above, as long as Cl is included. The chlorine-based gas includes, for example, Cl₂, SiCl₂, CHCl₃, CH₂Cl₂, CCl₄, and BCl₃. Further, there is no particular limitation to fluorine-based gas to be used for the dry etching described above, as long as F is included. The fluorine-based gas includes, for example, CHF₃, CF₄, C₂F₆, C₄F₈, and SF₆. Particularly, fluorine-based gas free of C can further reduce damage on a glass substrate for having a relatively low etching rate to a glass substrate.

The transfer mask 200 manufactured by the manufacturing method shown in FIG. 2 is a phase shift mask having a phase shift film 2 (phase shift pattern 2a) having a transfer pattern on the transparent substrate 1. The manufactured phase shift mask 200 of Example 1 was subjected to a mask pattern inspection by a mask inspection apparatus, and the presence of a black defect was confirmed on the phase shift pattern 2a of a location where a program defect was arranged. Therefore, the black defect portion was removed by an EB defect repair.

Manufacturing the phase shift mask 200 as described above can suppress generation of surface roughness of the transparent substrate 1 near the black defect portion and can also suppress generation of a spontaneous etching in the phase shift pattern 2a when an EB defect repair was performed on a black defect portion of the phase shift pattern 2a during manufacture of the phase shift mask 200.

Further, the method of manufacturing the semiconductor device of this disclosure is featured in using the phase shift mask 200 given above and subjecting a resist film on a semiconductor substrate to exposure-transfer of a transfer pattern.

Since the phase shift mask 200 and the mask blank 100 of this disclosure have the effects as described above, when the phase shift mask 200 is set on a mask stage of an exposure apparatus using an ArF excimer laser as an exposure light and a transfer pattern is exposure-transferred in a resist film on a semiconductor device, a transfer pattern can be transferred in the resist film on the semiconductor device at a high CD precision. Therefore, in the case where a lower layer film below the resist film was dry-etched to form a circuit pattern using the pattern of the resist film as a mask, a highly precise circuit pattern can be formed without short-circuit of wiring and disconnection caused by insufficient precision.

### Example 1

Examples 1 to 4 and Comparative Examples 1 and 2 are given below to further concretely describe the embodiments for carrying out this disclosure.

### [Manufacture of Mask Blank]

For each of Examples 1 to 4 and Comparative Examples 1 and 2, a transparent substrate 1 made of a synthetic quartz glass with a size of a main surface of about 152 mm×about 152 mm and a thickness of about 6.25 mm was prepared. An end surface and the main surface of the transparent substrate 1 were polished to a predetermined surface roughness, and thereafter subjected to predetermined cleaning treatment and drying treatment.

Next, the transparent substrate 1 was placed in a single-wafer RF sputtering apparatus, and by reactive sputtering (RF sputtering) by RF power source using a silicon (Si) target, with mixed gas of krypton (Kr), nitrogen (N₂), and helium (He) as sputtering gas, a lower layer A of the phase shift film 2 consisting of silicon and nitrogen was formed on the transparent substrate 1 as a lower layer 21 of the phase shift film 2 of Example 1. Similarly, lower layers B, C, D, E, and F of the phase shift films 2 consisting of silicon and nitrogen were formed on the respective transparent substrate 1 as the lower layer 21 of the phase shift film 2 of each of Examples 2 to 4 and Comparative Examples 1 and 2. For each of the lower layers A to F, power of the RF power source upon sputtering, flow rate ratio of the sputtering gas, and ratio of the number of presence of Si—Si bonds, SiₐN_{b} bonds, and Si₃N₄ bonds (abundance ratio) are shown in Table 1. In Table 1 and Table 2 to be explained below, the unit for the power (Pwr) is watt (W).

TABLE 1

| | film forming condition | | | | abundance ratio | | |
|---|---|---|---|---|---|---|---|
| | Pwr | Kr | N₂ | He | Si—Si | SiₐN_{b} | Si₃N₄ |
| lower | 1500 | 20 | 3.0 | 100 | 0.746 | 0.254 | 0.000 |
| layer A | | | | | | | |
| lower | 1500 | 20 | 2.3 | 100 | 0.898 | 0.102 | 0.000 |
| layer B | | | | | | | |
| lower | 1500 | 20 | 5.8 | 100 | 0.605 | 0.373 | 0.022 |
| layer C | | | | | | | |
| lower | 1500 | 20 | 7.0 | 100 | 0.574 | 0.382 | 0.044 |
| layer D | | | | | | | |
| lower | 1725 | 20 | 8.5 | 100 | 0.430 | 0.518 | 0.052 |
| layer E | | | | | | | |
| lower | 1725 | 20 | 2.0 | 100 | 0.978 | 0.022 | 0.000 |
| layer F | | | | | | | |

The ratio of the number of presence of Si—Si bonds, SiₐN_{b} bonds, and Si₃N₄ bonds (abundance ratio) of the lower layers A to F was calculated as follows. First, through the same film forming conditions as the lower layers 21 of the phase shift films 2 of Examples 1 to 4 and Comparative Examples 1 and 2, another lower layers A to F were formed on the main surfaces of another transparent substrates. The lower layers A to F were analyzed by an X-ray photoelectron spectroscopy. In the X-ray photoelectron spectroscopy, the steps of irradiating an X-ray (AlKα ray: 1486 eV) on the surfaces of the lower layers A to F to measure the intensity of photoelectrons emitted from the lower layers A to F, digging the surfaces of the lower layers A to F by Ar gas sputtering to about 0.65 nm, and irradiating an X-ray on the lower layers A to F of the dug regions to measure the intensity of photoelectrons emitted from those regions were repeated, and Si2p narrow spectrum of each depth of the lower layers A to F was obtained, respectively. Since the transparent substrate 1 is an insulating body, energy of the obtained Si2p narrow spectrum deviates at a rather low level compared to the spectrum when analyzed on a conductive body. To correct this deviation, correction is made to correspond to the peak of a carbon which is a conductive body.

The obtained Si2p narrow spectrum includes a peak for each of Si—Si bonds, SiₐN_{b} bonds, and Si₃N₄ bonds. Each peak position of Si—Si bonds, SiₐN_{b} bonds, and Si₃N₄ bonds, and full width at half maximum FWHM were fixed and a peak resolution was made. Concretely, a peak resolution was made with the peak position of Si—Si bonds at 99.35 eV, the peak position of SiₐN_{b} bonds at 100.6 eV, the peak position of Si₃N₄ bonds at 101.81 eV, and each full width at half maximum FWHM at 1.71. Area was calculated for each spectrum of Si—Si bonds, SiₐN_{b} bonds, and Si₃N₄ bonds subjected to peak resolution. The area was calculated by subtracting a background calculated by an algorithm of a publicly known method of the analysis device. Based on each area calculated for each spectrum, a ratio of the number of presence of Si—Si bonds, SiₐN_{b} bonds, and Si₃N₄ bonds was calculated.

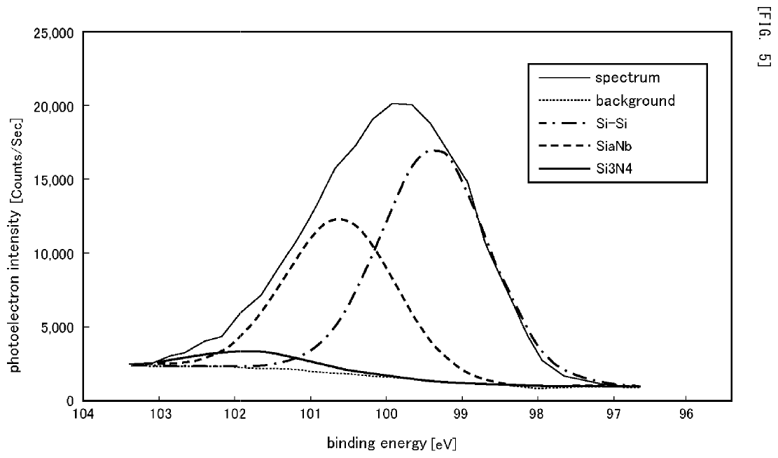

FIGS. 3, 4, and 5 are results of an X-ray photoelectron spectroscopy on the lower layer (lowermost layer) of the phase shift film of the mask blank according to each of Example 1, Example 3, and Comparative Example 1, among of which Si2p narrow spectrum at a predetermined depth is shown. As shown in the drawing, on the Si2p narrow spectrum, a peak resolution was made on each of the Si—Si bonds, SiₐN_{b} bonds, and Si₃N₄ bonds, an area was calculated by subtracting the background, and the ratios of the number of Si—Si bonds, SiₐN_{b} bonds, and Si₃N₄ bonds being present were calculated.

As a result, the lower layers A to D satisfied both the condition where a ratio of a number of Si₃N₄ bonds being present divided by a total number of Si₃N₄ bonds, SiₐN_{b} bonds, and Si—Si bonds present is 0.05 or less, and the condition where a ratio of a number of SiₐN_{b} bonds being present divided by a total number of Si₃N₄ bonds, SiₐN_{b} bonds, and Si—Si bonds being present is 0.1 or more, as shown in Table 1. On the other hand, the lower layer E did not satisfy the condition in which a number of Si₃N₄ bonds being present divided by a total number of Si₃N₄ bonds, SiₐN_{b} bonds, and Si—Sis bond being present is 0.05 or less. Further, the lower layer F did not satisfy the condition where a ratio of a number of SiₐN_{b} bonds being present divided by a total number of Si₃N₄ bonds, SiₐN_{b} bonds, and Si—Si bonds being present is 0.1 or more.

Next, the transparent substrate 1 to which the lower layer 21 of the phase shift film 2 is formed was placed in a single-wafer RF sputtering apparatus, and by reactive sputtering (RF sputtering) by RF power source using a silicon (Si) target, with mixed gas of krypton (Kr), nitrogen (N₂), and helium (He) as sputtering gas, an upper layer A of the phase shift film 2 containing silicon and nitrogen (SiN film Si:N:O=44 atom %:55 atom %:1 atom %) was formed as an upper layer 22 of the phase shift films 2 of Examples 1 and 3, and Comparative Example 1, on each of the lower layers 21 of Examples 1 and 3, and Comparative Example 1. Similarly, an upper layer B of the phase shift film 2 containing silicon and nitrogen (SiN film Si:N:O=44 atom %:55 atom %:1 atom %) was formed as an upper layer 22 of the phase shift films 2 of Examples 2 and 4 and Comparative Example 2 on each of the lower layers 21 of Examples 2 and 4 and Comparative Example 2. The composition of the upper layers A and B is the result obtained from measurement by X-ray photoelectron spectroscopy (XPS). Power of the RF power source upon sputtering and flow rate ratio of the sputtering gas for each of the upper layers A and B are shown in Table 2.

TABLE 2

| | | | | | abundance ratio | | |
|---|---|---|---|---|---|---|---|
| | film forming condition | | | | | | Si—O/ |
| | Pwr | Kr | N₂ | He | Si₃N₄ | SiₐN_{b} | Si—ON |
| upper | 1500 | 15 | 15 | 85 | 0.877 | 0.090 | 0.033 |
| Layer A | | | | | | | |
| upper | 1500 | 15 | 15 | 80 | 0.884 | 0.092 | 0.024 |
| Layer B | | | | | | | |

Next, for the purpose of adjusting stress of the film, the transparent substrates 1 of Examples 1 and 3 and Comparative Example 1 having the upper layers A formed thereon and the transparent substrates 1 of Examples 2 and 4 and Comparative Example 2 having the upper layers B formed thereon were subjected to heat treatment under the condition of 550° C. heating temperature in the atmosphere for the processing time of one hour.

The ratio of the number of presence of Si—Si bonds, SiₐN_{b} bonds, and Si₃N₄ bonds (abundance ratio) of the upper layers A and B are calculated as follows. First, through the same film forming conditions as the upper layers 22 of the phase shift films 2 of Examples 1 to 4 and Comparative Examples 1 and 2, another upper layers A and B were formed on the main surfaces of another transparent substrates, and further subjected to a heat treatment under the same condition. The upper layers A, B were analyzed by an X-ray photoelectron spectroscopy. In the X-ray photoelectron spectroscopy, the steps of irradiating an X-ray (AlKα ray: 1486 eV) on the surfaces of the upper layers A, B to measure the intensity of photoelectrons emitted from the upper layers A, B, digging the surfaces of the upper layers A, B by Ar gas sputtering up to a depth of 0.65 nm, and irradiating an X-ray on the upper layers A, B of the dug regions to measure an intensity of photoelectrons emitted from those regions were repeated, and Si2p narrow spectrum of each depth of the upper layers A, B was obtained, respectively. Since the transparent substrate 1 is an insulating body, energy of the obtained Si2p narrow spectrum deviates at a rather low level compared to the spectrum when analyzed on a conductive body. To correct this deviation, correction is made to correspond to the peak of a carbon which is a conductive body.

The obtained Si2p narrow spectrum includes a peak for each of Si₃N₄ bonds, SiₐN_{b} bonds, and Si—O/Si—ON bonds. Each peak position of Si₃N₄ bonds, SiₐN_{b} bonds, and Si—O/Si—ON bonds, and FWHM (full width at half maximum) were fixed and a peak resolution was made. Peak resolution could not be made on Si—Si bonds (detection lower limit or less). Area was calculated for each spectrum of Si₃N₄ bonds, SiₐN_{b} bonds, and Si—O/Si—ON bonds subjected to peak resolution. The area was calculated by subtracting a background calculated by an algorithm of a publicly known method of the analysis device. Based on each area calculated for each spectrum, a ratio of the number of presence of Si₃N₄ bonds, SiₐN_{b} bonds, and Si—O/Si—ON bonds was calculated, the result of which is shown in Table 2.

A transmittance and a phase difference of the phase shift films 2 of Examples 1 to 4 and Comparative Examples 1 and 2 to a light of 193 nm wavelength were measured using a phase shift measurement device (MPM193 manufactured by Lasertec). Further, the phase shift films 2 of Examples 1 to 4 and Comparative Examples 1 and 2 were analyzed by STEM (Scanning Electron Microscope) and EDX (Energy Dispersive X-Ray Spectroscopy), and formation of an oxidization layer was confirmed on the surface layer portion at a thickness of about 2 nm from the surface of the upper layer 22. Moreover, optical properties of the lower layer 21 and the upper layer 22, respectively, of the phase shift films 2 of Examples 1 to 4 and Comparative Examples 1 and 2 were measured. Table 3 shows the film thickness and optical properties of the lower layers 21 and the upper layers 22 of the phase shift films 2 of Examples 1 to 4 and Comparative Examples 1 and 2. In Table 3, the unit of film thickness is nanometer (nm), the unit of a transmittance and a back surface reflectance (where only the phase shift film 2 is present on the transparent substrate 1) is percent (%), and the unit of phase difference is degree.

TABLE 3

| | | lower layer | | | upper layer | | | | | back | | substrate |
|---|---|---|---|---|---|---|---|---|---|---|---|---|
| | layer | film | | | film | | | | phase | surface | spontaneous | surface |
| | structure | thickness | n | k | thickness | n | k | transmittance | difference | reflectance | etching | roughness |
| Example1 | lower layer A + | 11 | 1.40 | 2.25 | 62 | 2.58 | 0.39 | 4.4 | 179.5 | 38.6 | ∘ | ∘ |
| | upper layer A | | | | | | | | | | | |
| Example2 | lower layer B + | 9 | 1.29 | 2.39 | 64 | 2.56 | 0.35 | 6.0 | 179.7 | 38.4 | ∘ | ∘ |
| | upper layer B | | | | | | | | | | | |
| Example3 | lower layer C + | 16 | 1.52 | 2.09 | 58 | 2.58 | 0.39 | 2.9 | 178.3 | 38.0 | ∘ | ∘ |
| | upper layer A | | | | | | | | | | | |
| Example4 | lower layer D + | 14 | 1.54 | 2.05 | 60 | 2.56 | 0.35 | 4.2 | 180.6 | 36.7 | ∘ | ∘ |
| | upper layer B | | | | | | | | | | | |
| Comparative | lower layer E + | 14 | 1.58 | 1.99 | 59 | 2.58 | 0.39 | 3.9 | 179.6 | 35.5 | ∘ | x |
| Example1 | upper layer A | | | | | | | | | | | |
| Comparative | lower layer F + | 9 | 1.23 | 2.48 | 64 | 2.56 | 0.35 | 4.9 | 180.0 | 40.0 | x | ∘ |
| Example2 | upper layer B | | | | | | | | | | | |

Next, the transparent substrate 1 having the phase shift film 2 formed thereon was placed in a single-wafer DC sputtering apparatus, and by reactive sputtering (DC sputtering) using a chromium (Cr) target with mixed gas of argon (Ar), carbon dioxide (CO₂), nitrogen (N₂), and helium (He) as sputtering gas, a light shielding film 3 consisting of CrOCN (CrOCN film: Cr:O:C:N=55 atom %:22 atom %:12 atom %:11 atom %) was formed on the phase shift film 2 at a thickness of 46 nm. An optical density (OD) to a light of 193 nm wavelength in the stacked structure of the phase shift film 2 and the light shielding film 3 was 3.0 or more. Further, another transparent substrate 1 was prepared, only a light shielding film 3 was formed under the same film-forming conditions, optical properties of the light shielding film 3 were measured, and a refractive index n was 1.95 and an extinction coefficient k was 1.53.

Next, the transparent substrate 1 with the phase shift film 2 and the light shielding film 3 stacked thereon was placed in a single-wafer RF sputtering apparatus, and by RF sputtering using a silicon dioxide (SiO₂) target with argon (Ar) gas as a sputtering gas, a hard mask film 4 consisting of silicon and oxygen was formed on the light shielding film 3 at a thickness of 5 nm. Through the above procedure, the mask blank 100 having a structure where the phase shift film 2 of a two-layer structure, the light shielding film 3, and the hard mask film 4 are stacked on the transparent substrate 1 was manufactured.

### [Manufacture of Phase Shift Mask]

Next, the phase shift masks 200 of Examples 1 to 4 and Comparative Examples 1 and 2 were manufactured through the following procedure using the mask blanks 100 of Examples 1 to 4 and Comparative Examples 1 and 2. First, a surface of the hard mask film 4 was subjected to HMDS treatment. Subsequently, a resist film of a chemically amplified resist for electron beam writing was formed in contact with a surface of the hard mask film 4 by spin coating at a film thickness of 80 nm. Next, a first pattern, which is a phase shift pattern to be formed in the phase shift film 2, was written by an electron beam on the resist film, predetermined cleaning and developing treatments were conducted, and a first resist pattern 5a having the first pattern was formed (see FIG. 2(a)). At this stage, a program defect was added to the resist pattern 5a that was written by electron beam in addition to the transfer pattern that is to be originally formed, so that a black defect is formed in the phase shift film 2.

Next, dry etching using CF₄ gas was conducted with the first resist pattern 5a as a mask, and a first pattern (hard mask pattern 4a) was formed in the hard mask film 4 (see FIG. 2(b)). Thereafter, the first resist pattern 5a was removed.

Subsequently, dry etching was conducted using mixed gas of chlorine and oxygen (gas flow ratio Cl₂:O₂=10:1) with the hard mask pattern 4a as a mask, and a first pattern (light shielding pattern 3a) was formed in the light shielding film 3 (see FIG. 2(c)). Next, dry etching was conducted using fluorine-based gas (SF₆+He) with the light shielding pattern 3a as a mask, and a first pattern (phase shift pattern 2a) was formed in the phase shift film 2, and at the same time the hard mask pattern 4a was removed (see FIG. 2(d)).

Next, a resist film of a chemically amplified resist for electron beam writing was formed on the light shielding pattern 3a by spin coating at a film thickness of 150 nm. Next, a second pattern, which is a pattern (light shielding pattern) to be formed in the light shielding film, was exposed and written in the resist film, further subjected to predetermined treatments such as developing, and a second resist pattern 6b having the light shielding pattern was formed (see FIG. 2(e)). Subsequently, dry etching was conducted using mixed gas of chlorine and oxygen (gas flow ratio Cl₂:O₂=4:1) with the second resist pattern 6b as a mask, and a second pattern (light shielding pattern 3b) was formed in the light shielding film 3 (see FIG. 2(f)). Further, the second resist pattern 6b was removed, predetermined treatments such as cleaning were carried out, and the phase shift mask 200 was obtained (see FIG. 2(g)).

The manufactured phase shift masks 200 of Examples 1 to 4 and Comparative Examples 1 and 2 were subjected to a mask pattern inspection by a mask inspection apparatus, and the presence of a black defect was confirmed on the phase shift pattern 2a of a location where a program defect was arranged. The black defect portion was subjected to an EB defect repair. As shown in Table 3, the repair rate ratio of the phase shift pattern 2a relative to the transparent substrate 1 in Examples 1 to 4 was sufficiently high, and etching on the surface of the transparent substrate 1 could be minimized. On the other hand, in Comparative Example 1, the repair rate ratio of the phase shift pattern 2a relative to the transparent substrate 1 was low, and an advancement of etching on the surface (surface roughness) of the transparent substrate 1 was observed. In Comparative Example 2, an occurrence of an undercut was observed caused by the repair rate being too fast. Moreover, an advancement of an etching phenomenon due to the sidewall of the phase shift pattern 2a around the black defect portion being contacted by unexcited XeF₂ gas supplied upon EB defect repair, namely, a spontaneous etching, was observed.

A simulation of a transfer image was made when an exposure transfer was made on a resist film on a semiconductor device using AIMS193 (manufactured by Carl Zeiss) at an exposure light of wavelength 193 nm on the phase shift masks 200 of Examples 1 to 4 and Comparative Examples 1 and 2 after the EB defect repair. The simulated exposure transfer images were inspected, and the design specification was fully satisfied when the phase shift masks 200 of Examples 1 to 4 were used. Further, the transfer images of the portions subjected to the EB defect repair were at a comparable level to the transfer images of other regions. In view of the above result, it can be considered that when an EB defect repair was performed on a black defect portion of the phase shift pattern 2a of the phase shift masks 200 of Examples 1 to 4, generation of surface roughness of the transparent substrate 1 can be suppressed and generation of a spontaneous etching in the phase shift pattern 2a can also be suppressed. It can be understood that when the phase shift masks 200 of Examples 1 to 4 after an EB defect repair are set on a mask stage of an exposure apparatus and exposure-transferred on a resist film on a semiconductor device, a circuit pattern to be finally formed on the semiconductor device can be formed with high precision. Therefore, the phase shift masks 200 of Examples 1 to 4 can be considered as phase shift masks with high transfer precision.

The simulated exposure transfer image was inspected on the phase shift mask 200 of Comparative Example 1, resulting in CD reduction in the phase shift pattern also in portions other than those subjected to an EB defect repair, which is considered as caused by slow etching rate in dry etching in forming a pattern in the phase shift film. Further, the transfer image of the portion subjected to an EB defect repair was at a level where a transfer defect will occur caused by an influence of surface roughness of the transparent substrate, etc. It can be understood from this result that when the phase shift mask of Comparative Example 1 after an EB defect repair was set on a mask stage of an exposure apparatus and exposure-transferred on a resist film on a semiconductor device, generation of short-circuit or disconnection of circuit pattern is expected on a circuit pattern to be finally formed in the semiconductor device.

The simulated exposure transfer image was inspected on the phase shift mask 200 of Comparative Example 2, and surface roughness of the transparent substrate 1 at the portion subjected to an EB defect repair could not be observed. However, the transfer image around the portion subjected to an EB defect repair was at a level where a transfer defect will occur caused by an influence of a spontaneous etching, etc. It can be understood from this result that when the phase shift mask of Comparative Example 2 after an EB defect repair was set on a mask stage of an exposure apparatus and exposure-transferred on a resist film on a semiconductor device, generation of short-circuit or disconnection of circuit pattern is expected on a circuit pattern to be finally formed in the semiconductor device.

### DESCRIPTION OF REFERENCE NUMERALS

1 transparent substrate
2 phase shift film
21 lower layer (lowermost layer)
22 upper layer
2a phase shift pattern (transfer pattern)
3 light shielding film
3a,3b light shielding pattern
4 hard mask film
4a hard mask pattern
5a first resist pattern
6b second resist pattern
100 mask blank
200 phase shift mask

1. A mask blank comprising:
a transparent substrate; and
a phase shift film on the transparent substrate,
wherein:
the phase shift film comprises a lowermost layer, in contact with the transparent substrate, and one or more layers on the lowermost layer,
the one or more layers of the phase shift film consist of silicon and one or more elements selected from a metalloid element and a non-metallic element,
the lowermost layer consists of silicon and nitrogen, or silicon, nitrogen, and one or more elements selected from a metalloid element and a non-metallic element,
a ratio of a number of Si₃N₄ bonds present in the lowermost layer to a total number of Si₃N₄ bonds, SiₐN_{b} bonds (provided that b/[a+b]<4/7]), and Si—Si bonds present in the lowermost layer is 0.05 or less, and
a ratio of SiₐN_{b} bonds present in the lowermost layer to a total number of Si₃N₄ bonds, SiₐN_{b} bonds, and Si—Si bonds present in the lowermost layer is 0.1 or more.

2. The mask blank according to claim 1, wherein a total content of nitrogen and oxygen in the one or more layers is 50 atom % or more.

3. The mask blank according to claim 1, wherein a nitrogen content in the one or more layers is 50 atom % or more.

4. The mask blank according to claim 1, wherein the lowermost layer consists of silicon, nitrogen, and a non-metallic element.

5. The mask blank according to claim 1, wherein a ratio of a number of Si₃N₄ bonds present in the one or more layers to a total number of Si₃N₄ bonds, SiₐN_{b} bonds, Si—Si bonds, Si—O bonds, and Si—ON bonds present in the one or more layers is 0.87 or more.

6. The mask blank according to claim 1, wherein a thickness of the lowermost layer is 16 nm or less.

7. The mask blank according to claim 1, wherein a transmittance of the phase shift film with respect to an exposure light of an ArF excimer laser is 2% or more, and
wherein the phase shift film is configured to transmit the exposure light such that the transmitted light has a phase difference of 150 degrees or more and 200 degrees or less with respect to the exposure light transmitted through air for a same distance as a thickness of the phase shift film.

8. The mask blank according to claim 1 comprising a light shielding film on the phase shift film.

9. A phase shift mask comprising:
a transparent substrate; and
a phase shift film with a transfer pattern on the transparent substrate,
wherein:
the phase shift film comprises a lowermost layer, in contact with the transparent substrate, and one or more layers on the lowermost layer,
the one or more layers of the phase shift film consist of silicon and one or more elements selected from a metalloid element and a non-metallic element,
the lowermost layer consists of silicon and nitrogen, or silicon, nitrogen, and one or more elements selected from a metalloid element and a non-metallic element,
a ratio of a number of Si₃N₄ bonds present in the lowermost layer to a total number of Si₃N₄ bonds, SiₐN_{b} bonds (provided that b/[a+b]<4/7]), and Si—Si bonds present in the lowermost layer is 0.05 or less, and
a ratio of a number of SiₐN_{b} bonds present in the lowermost layer to a total number of Si₃N₄ bonds, SiₐN_{b} bonds, and Si—Si bonds present in the lowermost layer is 0.1 or more.

10. The phase shift mask according to claim 9, wherein a total content of nitrogen and oxygen in the one or more layers is 50 atom % or more.

11. The phase shift mask according to claim 9, wherein a nitrogen content in the one or more layers is 50 atom % or more.

12. The phase shift mask according to claim 9, wherein the lowermost layer consists of silicon, nitrogen, and a non-metallic element.

13. The phase shift mask according to claim 9 wherein a ratio of a number of Si₃N₄ bonds present in the one or more layers to a total number of Si₃N₄ bonds, SiₐN_{b} bonds, Si—Si bonds, Si—O bonds, and Si—ON bonds present in the one or more layers is 0.87 or more.

14. The phase shift mask according to claim 9, wherein a thickness of the lowermost layer is 16 nm or less.

15. The phase shift mask according to claim 9, wherein a transmittance of the phase shift film with respect to an exposure light of an ArF excimer laser is 2% or more, and
wherein the phase shift film is configured to transmit the exposure light such that the transmitted light has a phase difference of 150 degrees or more and 200 degrees or less with respect to the exposure light transmitted through air for a same distance as a thickness of the phase shift film.

16. The phase shift mask according to claim 9 comprising a light shielding film having a light shielding pattern formed on the phase shift film.

17. A method of manufacturing a semiconductor device comprising using the phase shift mask according to claim 9 to exposure-transfer a transfer pattern in a resist film on a semiconductor substrate.

18. The mask blank according to claim 1, wherein the lowermost layer consists of silicon, nitrogen, and one or more elements selected from boron, germanium, antimony, tellurium, carbon, oxygen, fluorine, hydrogen, helium, argon, krypton, and xenon.

19. The phase shift mask according to claim 9, wherein the lowermost layer consists of silicon, nitrogen, and one or more elements selected from boron, germanium, antimony, tellurium, carbon, oxygen, fluorine, hydrogen, helium, argon, krypton, and xenon.
